(19) United States
(12) Patent Application Publication
(10) Pub. No.: US 2003/0116439 A1
(43) Pub. Date: Jun. 26, 2003

(54) Method for forming encapsulated metal interconnect structures in semiconductor integrated circuit devices

(75) Inventors: Soon-Chen Seo, White Plains, NY (US); Carlos J. Sambucetti, Croton-on-Hudson, NY (US); Xiaomeng Chen, Poughkeepsie, NY (US); Zheng Chen, Poughkeepsie, NY (US); Vincent McGahay, Poughkeepsie, NY (US); Daniel C. Edelstein, White Plains, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 10/026,176

(22) Filed: Dec. 21, 2001

(51) Int. Cl. C25D 5/02; H05K 3/00; C25D 5/48

(52) U.S. Cl. 205/125; 205/220; 205/221

(57) ABSTRACT

An advanced back-end-of-line (BEOL) integration scheme for semiconductor devices using very low-k dielectric materials is disclosed. The disclosed method for forming a metal interconnect structure in a semiconductor integrated circuit device comprises forming the metal interconnects using a through-mask plating (TMP) process, and encapsulating the interconnects with a barrier layer by selectively depositing a barrier layer material using an electroless liner plating process or by non-selectively depositing a blanket insulator diffusion barrier layer using PVD or CVD techniques.

### FIELD OF THE INVENTION

This invention relates generally to the manufacture of semiconductor integrated circuit devices, and more particularly to an advanced back-end-of-line (BEOL) integration scheme for semiconductor devices using very low-k dielectric materials. The invention is directed to a method for forming an encapsulated metal interconnect structure in a semiconductor integrated circuit device. The metal interconnects are formed using a through-mask plating technique and encapsulated using an electroless liner plating process.

### BACKGROUND OF THE INVENTION

In conventional BEOL integration schemes, interconnect lines and vias are typically formed using a dual damascene process. First, the interlayer dielectric (ILD) material is deposited, and then openings for the lines and vias are patterned by photolithography and opened by plasma etching or reactive ion etching (RIE) processes. Typically, the line openings are formed first, and then the via openings are formed below the line openings. Next, copper or other metal is deposited in the ILD openings. A conductive liner may be deposited prior to the copper deposition, in order to protect against copper diffusion and electromigration. The liner is typically deposited using a vacuum deposition technique. The copper or other metal typically not only fills the ILD openings but also covers the entire semiconductor wafer. Therefore, excess metal must be removed by a chemical-mechanical polish (CMP) process or an etchback process so that only the metal in the line and via openings remains.

For example, a typical dual damascene interconnect formation process is disclosed in U.S. Pat. No. 6,153,935. In this dual damascene process, a dielectric layer is deposited over a substrate, then a CMP-stop layer is deposited over the dielectric layer. A trench is formed through the CMP-stop layer and partially into the dielectric layer, using conventional photolithography patterning and RIE etching processes. The trench is then lined with a conductive liner, using chemical vapor deposition (CVD), physical vapor deposition (PVD), or other conventional deposition techniques. A preferred material for the conductive liner is cobalt tungsten phosphide (CoWP), as disclosed in U.S. Pat. No. 5,695,810. The trench is next filled with a conductive material, using conventional deposition techniques such as evaporation, sputtering, CVD, electroless deposition, or electroplating. The conductive liner and conductive material typically not only fill the trench but also cover the entire surface of the dielectric layer. It is therefore necessary to remove the excess material from the surface of the CMP-stop layer, using either CMP or an etchback process.

However, there are several problems associated with dual damascene processes used to form advanced interconnect structures. As device size shrinks, it is becoming increasingly challenging to achieve critical dimensions of interconnect lines and vias in the ILD material, especially in very low-k materials, by using conventional lithographic resist patterning and etching processes. Achieving smaller interconnect sizes requires high resolution lithography techniques to pattern the photoresist material and etching techniques such as reactive ion etching (RIE) or dry plasma etching to pattern the underlying ILD material. However, these etching techniques are rendered complicated by the use of advanced low-k dielectric materials. It is increasingly difficult to control process conditions such that bowing, taper or undercut of the vias and trenches do not result.

Another problem with dual damascene processes is the relatively high cost of manufacturing associated with vacuum deposition techniques used for depositing the diffusion barrier liner. Vacuum deposition techniques include physical vapor deposition (PVD) and chemical vapor deposition (CVD). PVD involves coating the surface of a substrate with a compound in the vapor phase by physical adsorption or sputtering. In a CVD process, a chemical reaction occurs on the surface of a substrate between the substrate and a chemical compound in the vapor phase. Both PVD and CVD are typically conducted in a vacuum, or under reduced pressure conditions, requiring costly vacuum pump equipment and system controls. In addition, CVD should be conducted within a precise temperature range, requiring costly heating equipment and temperature controls. CVD also requires very expensive precursor chemicals and complicated precursor chemical delivery system.

In addition, it is becoming increasingly difficult to achieve continuous liner coverage on aggressive dual damascene structures using conventional vacuum deposition techniques. Most PVD techniques are typically performed using a plasma process, which provides a very directional ion beam flux, creating relatively thick deposition on horizontal surfaces of vias and trenches, but thinner coverage on the sidewalls of vias or trenches. In aggressive dual damascene structures with high aspect ratios, i.e., where the total height of dual damascene trenches and vias (or total ILD thickness) is larger than three times the width of the vias, sidewall coverage is extremely poor and may result in discontinuous coverage. Liner coverage which is too thin or discontinuous on any surface will result in copper migration through such holes, causing reliability problems. CVD techniques provide better coverage than PVD techniques. However, CVD techniques are generally more costly and have lower throughput than PVD techniques.

Removal of excessive metal by CMP is also relatively expensive. Copper or other metal is often deposited in the via and trench openings by a plating process.

Typically, plating occurs inside the vias from all sides and overfills the surface of the vias substantially, resulting in an “overburden” or “overplating” layer on top of the vias. This copper overburden must be removed by a costly CMP process. An alternative method for forming interconnect structures involves through-mask plating (TMP). A typical TMP process begins with deposition of a seed layer or plating base on a substrate. Next, a layer of disposable material is deposited and patterned to expose regions of the seed layer. The disposable material may be, for example, a dielectric material or a polymer resist material. These exposed regions of the seed layer are plated with an electrically conductive material to form the interconnects, using either an electrolytic plating process (electroplating) or an electroless plating process. Finally, the disposable material and seed layer in regions not plated with the interconnects are removed, and the ILD material is deposited in the areas between the interconnects. A typical TMP process for forming interconnects is disclosed in U.S. Pat. No. 4,810,332.

The TMP process eliminates many of the problems associated with the dual damascene process. However, the TMP process does not allow for deposition of a diffusion barrier layer (or liner) prior to interconnect formation, as is the case in a typical dual damascene process. Blanket deposition of the metal diffusion barrier layer (or liner) after the interconnects are formed and the disposable material and seed layer are removed will result in shorts between the interconnects, as metal barrier layer material is deposited on the substrate between the interconnects as well as on the interconnects. Thus, one needs to deposit metal diffusion barrier layer selectively on interconnect metal or to deposit non-selective blanket insulator diffusion barrier layer where both techniques are relatively easy to process and provide robust barrier layer coverage. Selective metal diffusion barrier layer deposition using the electroless plating process provides very uniform and conformal liner coverage. Non-selective blanket insulator diffusion barrier layer deposition using PVD or CVD onto the interconnect wires also improves liner coverage around protruded vias and lines over blanket liner deposition inside the dual damascene structure.

Therefore, there is a need in the art for an interconnect formation method that does not rely on a dual damascene process involving photolithography patterning and RIE etching.

There is also a need in the art for an interconnect formation method that does not require a costly vacuum deposition technique for diffusion barrier liner deposition, and does not require a costly CMP process following metal deposition or plating.

There is also a need in the art for a method of selectively or non-selectively encapsulating non-dual damascene interconnects with a barrier layer material to protect against copper diffusion and electromigration.

### SUMMARY OF THE INVENTION

The problems described above are addressed through use of the present invention, which is directed to a method for forming a metal interconnect structure in a semiconductor integrated circuit device. In this method, metal is plated selectively in the line and via openings using a TMP technique. Then, the metal interconnects are encapsulated using a selective electroless plating process or a non-selective insulator diffusion barrier deposition process. Following interconnect metal deposition and encapsulation, the ILD material is applied and cured, and the overburden ILD layer is polished off using a conventional CMP process or RIE process.

The TMP process eliminates the need for patterning the ILD using lithography and RIE processes, and also eliminates the need for excessive metal CMP to remove the metal overburden as is required in conventional damascene processes. The electroless liner plating step or insulator diffusion barrier deposition using CVD or PVD provides improved liner coverage around the interconnect lines and vias, to protect against copper diffusion and electromigration. Cost of manufacturing is also substantially reduced by replacing costly liner deposition processes with the selective electroless liner plating step, and also by eliminating the need for costly photolithography patterning and etching of the ILD and subsequent removal of excessive liner and metal by CMP.

Accordingly, a method for forming a metal interconnect in an integrated circuit device is disclosed. The method comprises the steps of: depositing a metal seed layer onto a partially fabricated integrated circuit device; depositing a photoresist layer onto the metal seed layer; forming an opening in the photoresist layer by a photolithography process, thereby exposing a portion of the metal seed layer; depositing metal in the opening by a plating process; removing the photoresist layer and metal seed layer, thereby exposing the partially fabricated integrated circuit device; depositing a conformal barrier layer onto the metal; and depositing a dielectric material onto the partially fabricated integrated circuit device. The metal may be deposited using an electrolytic plating process or an electroless plating process. The conformal barrier layer may be selectively deposited using an electroless plating process which comprises the steps of: depositing catalytic particles onto the surface of the metal; and immersing the partially fabricated integrated circuit device into a plating bath, or may be non-electively deposited using PVD or CVD techniques.

### BRIEF DESCRIPTION OF THE DRAWINGS

The features of the invention believed to be novel and the elements characteristic of the invention are set forth with particularity in the appended claims. The drawings are for illustration purposes only and are not drawn to scale. Furthermore, like numbers represent like features in the drawings. The invention itself, however, both as to organization and method of operation, may best be understood by reference to the detailed description which follows, taken in conjunction with the accompanying drawings, in which:

FIGS. 1-18 illustrate a preferred method of the present invention showing cross-sectional views of a partially fabricated semiconductor integrated circuit device; and

FIG. 19 illustrates a cross-sectional view of a partially fabricated semiconductor integrated circuit device formed using the method of the present invention.

### DETAILED DESCRIPTION OF THE INVENTION

The invention will now be described by reference to the accompanying figures. In the figures, various aspects of the structures have been shown and schematically represented in a simplified manner to more clearly describe and illustrate the invention. For example, the figures are not intended to be to scale. In addition, the vertical cross-sections of the various aspects of the structures are illustrated as being rectangular in shape. Those skilled in the art will appreciate, however, that with practical structures these aspects will most likely incorporate more tapered features. Moreover, the invention is not limited to constructions of any particular shape.

Although certain aspects of the invention will be described with respect to a structure comprising copper, the invention is not so limited. Although copper is the preferred conductive material, the structure of the present invention may comprise any conductive material known in the art to form interconnects by a TMP process. Copper is preferred because of its low bulk resistivity of 1.67 μOhm at 20-25° C. Silver, with a resistivity of 1.59 μOhm at 20-25° C., is another conductive material suitable for high performance interconnect circuit build.

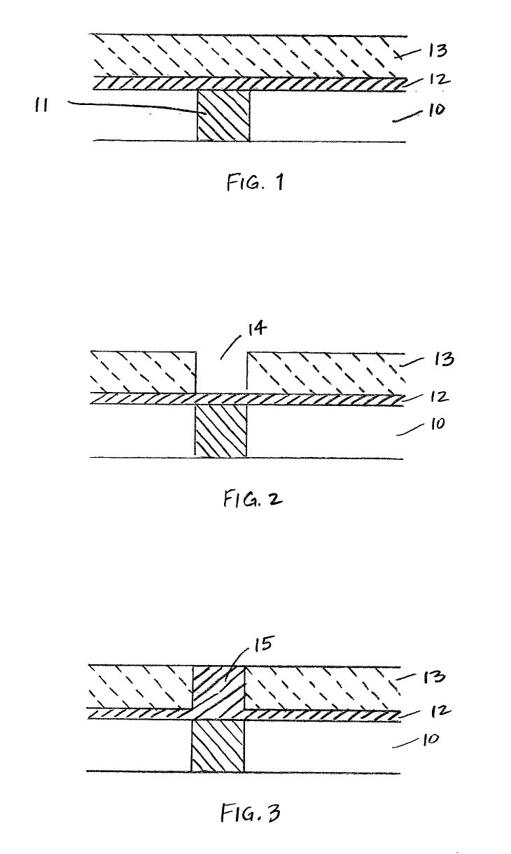

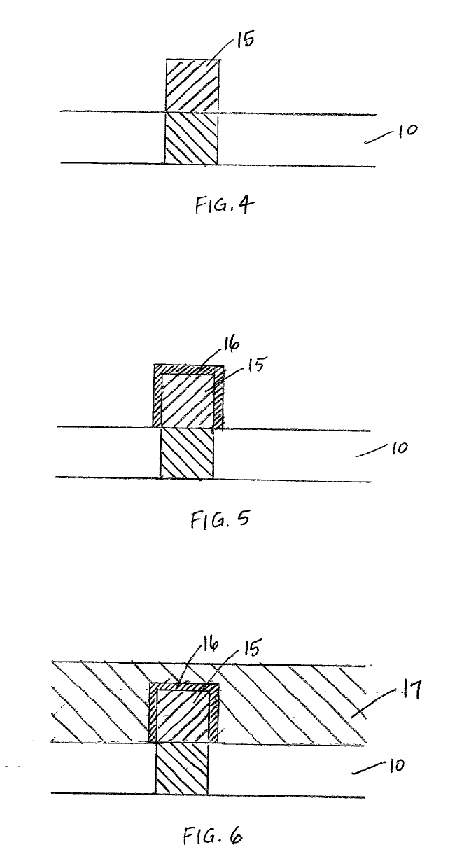

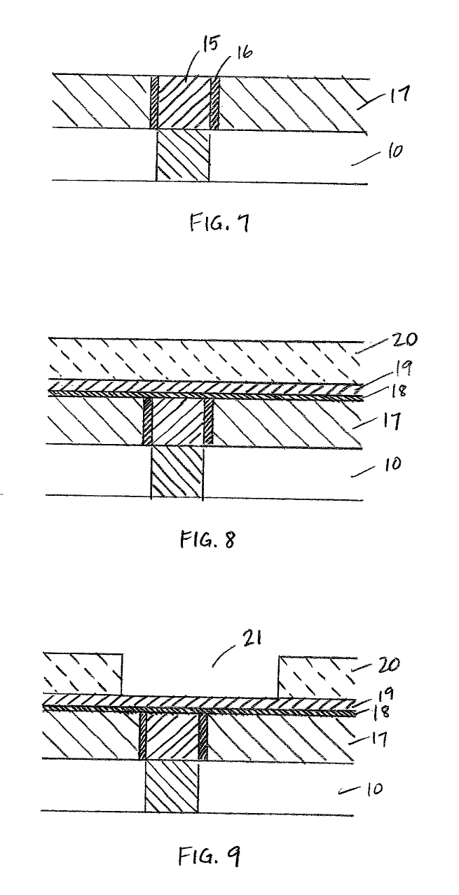

Referring to FIG. 1, a partially fabricated semiconductor integrated circuit device or chip 10 is shown, with device features such as an interconnect via 11. The method of the present invention begins with deposition of seed layer or plating base 12 on substrate 10. Seed layer 12 is preferably electrically conducting, adherent to substrate 10, and has a surface conducive to the subsequent growth of a plated deposit (e.g., free of a passivating oxide). If the subsequent plated interconnect deposit is formed by electrolytic plating, seed layer 12 should further be in a single, topographically connected piece.

For copper BEOL interconnect wiring, the preferred seed layer material is copper. Copper seed layer 12 may be deposited using chemical vapor deposition (CVD) or physical vapor deposition (PVD). The preferred deposition method is PVD because of reduced cost, higher manufacturing throughput and lower maintenance. Alternatively, one could use any conducting barrier layer which allows direct electroplating without a copper seed layer, such as W, TaN or CoWP. The optimum thickness of seed layer 12 depends on the minimum ground rule dimension of the interconnect wires. Seed layer 12 should be continuous, and should be thick enough to carry plating current without burning. On the other hand, seed layer 12 should be thin enough such that a mild acid will etch away the seed layer without substantially etching away subsequently formed interconnect wires. Thus, the preferred thickness for a seed layer is about 10% of the total ILD thickness or height. For submicron technology, e.g., ILD thickness or height of 500 nm, the preferred seed layer thickness is about 30 nm to 50 nm.

Following deposition of seed layer 12, photoresist layer 13 is deposited on the partially fabricated semiconductor chip. In FIG. 2, at least one opening 14 is formed in photoresist layer 13, using conventional photolithography techniques. The basic steps of a conventional lithographic process include exposure and development. The photoresist material is applied as a thin coating 13 over the partially fabricated semiconductor chip, and is subsequently exposed through a mask such that light strikes selected areas of the resist material. The exposed resist is then subjected to a development step, which generally involves immersion in an appropriate solvent. Depending on the chemical nature of the resist material, the exposed areas may be rendered more soluble in the developing solvent than the unexposed areas, thereby producing a positive tone image of the mask. A three-dimensional relief image is produced in the resist material which is a replication of the opaque and transparent areas of the mask. By this process, at least one opening 14, such as a via 14, is produced in photoresist layer 13.

Positive resist materials are preferred because of their inherently higher resolution. Patterning resolution can be further improved by shifting to shorter wavelength UV light or excimer laser. Deep-UV systems use a line-narrowed excimer laser operating at 248 nm or 193 nm. Commercial exposure tools that operate in the deep-UV region of the spectrum are available from, e.g., ASML and Nikon. Dose conditions depend on the sensitivities of the resists, but are generally in the range of about 10-150 mJ/cm².

In FIG. 3, interconnect via 15 is formed by selective plating of a conductive material such as copper in via 14. This selective plating step can be performed using either an electrolytic or electroless plating technique. The preferred plating method is electrolytic plating, or electroplating, because it offers higher manufacturing throughput and simpler bath chemistry. The copper electroplating bath contains a dissolved cupric salt. The concentration of the cupric salt is at least about 0.4 molar and preferably at least about 0.8 molar. The maximum cupric salt concentration is determined by the solubility limit of the solution. The cupric ion may be added as sulfamate, hydroxide, carbonate or other salt that is compatible with the plating bath chemistry and an addition agent. The preferred salt is CuSO₄, and is obtained from copper sulfate pentahydrate.

The electroplating bath typically has an acidic pH of up to about 5. The pH of the bath is preferably about 0.6. A low pH is desirable in order to dissolve and polarize the copper anode and improve the grain structure. To achieve this low pH, the electroplating bath may include an inorganic acid in a concentration of up to about 0.5 molar. The preferred acid is H₂SO₄. Alternatively, sulfonic acid, methanesulfonic acid, hydrochloric acid, or other acid with comparable bath function may be used.

The plating bath may contain HCl in an amount of about 2 milli-molar (mM). There are several roles of HCl. HCl may help control the plated film properties and superfill capability. HCl also dissolves the copper anode and replenishes copper ions to the bath. HCl may also precipitate silver if there are any silver impurities in the anode.

In addition, the electroplating bath of the present invention may optionally contain auxiliary additives for controlling such properties of the electroplated copper as grain structure, ductility and internal stress. Preferred additive systems include “Sabre” and ViaForm™ (both available from Enthone-OMI, Inc.) “Sabre” includes two additives: “Sabre B” and “Sabre L.” ViaForm includes three additives: “Accelerator,” “Suppressor,” and “Leveler.” Another suitable additive system is “Copper Gleam 2001” (available from Shipley, Inc.), which includes “Copper Gleam 2001 Leveler” and “Copper Gleam 2001 Carrier.” A third suitable additive system is Nanoplate™ 2001 (also available from Shipley, Inc.), which includes “C-2001” and “B-2001.”

The current density applied on the cathode is about 0.1 to 20 mA/cm². Plating current may be DC or pulsed type, and may consist of multiple current steps. The initial current may be applied without any wetting or dwell time, and is typically about 0.1 to about 5 mA/cm² for a time of about 50 milliseconds to about 40 seconds. The preferred current step is about 3.3 mA/cm² for about 11 seconds, followed by 15 mA/cm² for a time sufficient to fill the feature completely (about 35-40 seconds to fill 300 nm deep features). The preferred current type is DC. Bath agitation and wafer rotation may be necessary to enhance mass transport during plating. Bath agitation should be adjusted by wafer rotation (preferably 125 rpm) and flow rate (preferably 6 liter/min.) of bath solution to the plating cell. Electroplating may be performed using various tools for semiconductor copper BEOL integration commercially available from, e.g., Novellus, Semitool, and Applied Materials.

Following formation of via 15 by electroplating, photoresist layer 13 and seed layer 12 are removed, leaving a standing copper stud 15, as shown in FIG. 4. Photoresist layer 13 may be removed by dry etching (e.g., in oxygen plasma) or by wet etching (e.g., acetone). Photoresist is commonly removed by high power oxygen plasma at elevated temperature (about 300° C.). However, exposing copper to oxygen, and to sulfur from the photoresist, may result in detrimental oxidation of the copper and formation of copper sulfide (CuS₂). Alternatively, photoresist may be removed at low temperature (e.g., room temperature or lower) in a RIE chamber using oxygen plasma. However, this technique may still result in residual copper sulfide formation. Therefore, it is preferred to remove photoresist layer 13 using a solvent such as acetone, ethyl lactate, or other solvent appropriate for the particular photoresist being used. Solvent removal is possible only if the resist is not strongly “hardened” (i.e., crosslinked) or skinned, such as would occur if the resist were exposed to RIE processing. In the method of this invention, no RIE processing is necessary, and the resist is therefore removable by solvents.

Copper seed layer 12 may be removed by a conventional chemical etching process, or by an advanced plasma etching process. Ammonium persulfate etch chemistries are commonly used to remove copper seed layers. However, such etch solutions may undercut the interconnects. Therefore, a removal process involving chlorine-based dry etching, sputtering or ion milling is preferred, followed by a wet clean or cryogenic aerosol clean to remove residual metal particles and chlorine byproducts.

A conformal barrier layer 16 is next formed on via 15, as shown in FIG. 5. Barrier layer 16 protects against copper diffusion and electromigration. Barrier layer 16 is preferably deposited by an electroless liner plating process which comprises two steps: selective substrate (e.g., copper surface) activation, and selective metal deposition on the activated portion of the substrate.

The surface of copper via 15 may be activated by the incorporation of nanometer-sized catalytic particles such as palladium, cobalt or nickel onto the copper surface. These catalytic particles may be applied using a physical deposition process such ion implantation, or by a chemical deposition process. A selective chemical deposition process is preferred, so that catalytic plating will not occur on insulator surfaces.

The function of the catalytic particles is to catalyze and initiate the electrochemical deposition reaction when the substrate is subsequently immersed into an electroless plating bath. In the present invention, since the preferred substrate is the surface of copper interconnect lines or vias, the following selective exchange reaction is preferred to achieve activation:

Cu(metal)+Pd(ions)→Cu(ions)+Pd(nanoparticles)

The effect of this exchange is to cover the surfaces of the copper lines and vias with a monolayer of palladium particles, which act as a catalytic surface for the subsequent electroless deposition of the barrier layer. The copper surfaces may be activated by immersing the substrate in a very dilute palladium ionic solution for a few seconds.

For example, the catalytic particles may be applied by immersion into a solution of a palladium salt in an acid medium. Preferably, the substrate including copper via 15 is immersed for 60 seconds in a solution of palladium sulfate made by dissolving 0.05 grams of palladium sulfate (PdSO₄) in 1 liter of 0.5 molar H₂SO₄. The time of immersion should be at least about 30 seconds to achieve activation, but the time of immersion should be no more than about 120 seconds to avoid depositing too much palladium on the copper surface, which can result in bridging between the copper lines. The concentration of palladium sulfate in the solution should be at least about 0.02 grams PdSO₄ in 1 liter of 0.5 molar H₂SO₄, and should be no more than about 0.2 grams PdSO₄ in 1 liter of 0.5 molar H₂SO₄. Sulfuric acid in a concentration of at least about 0.5 molar should be used to avoid producing an unstable solution in which palladium ions will precipitate out of the solution.

After activation of the copper surfaces, barrier layer 16 is deposited on the copper surface of via 15 by an electroless plating process. Barrier layer 16 is preferably formed of an electrically conductive alloy such as CoP, NiP, CoWP, NiWP, CoB, NiB, or CoWB. A most preferred alloy is CoWP. Upon immersion in an electroless plating bath, a conductive layer is deposited on the catalyzed area of the substrate. The thickness of the plated barrier layer 16 depends primarily on the time of exposure to the plating bath. A preferred thickness is about 5 to 20 nm, most preferably about 10 nm. A preferred time of exposure to the plating bath is about 1 minute.

A suitable electroless plating system is based on the use of the hypophosphite reducing agent. In this system, a mixture of hypophosphite ions and cobalt or nickel ions is formed, together with citrate stabilizing agent, at a suitable pH and temperature (usually between about 65 and 75° C.). When the activated substrate described above is immersed in this plating bath, the following reaction occurs on the substrate:

Co⁽²⁺⁾+2H₂PO₂⁽⁻⁾+2OH⁽⁻⁾+Cu(Pd)→Co/Cu metal+2H₂PO₃⁽⁻⁾+2H⁽⁺⁾

The cobalt metal is then deposited selectively on top of the catalyzed palladium layer on the substrate.

Even if it is possible to use conventional electroless plating baths containing a mixture of hypophosphite ions and cobalt or nickel ions, it has been found that the films produced by these baths do not possess the electromigration enhancement for copper circuits, and do not exhibit the desired adhesion to copper. Therefore, it is preferable to add ammonium tungstate to the electroless solution to generate a film of CoWP, which presents outstanding adhesion to copper and dielectrics and increases the electromigration lifetime of copper circuits.

The pH of the electroless plating bath should be about 8 to about 10, and is preferably about 9.5. The temperature of the electroless plating bath should be about 65° C. to about 80° C., and is preferably about 78° C. The hypophosphite reducing agent is preferably sodium hypophosphite, and should be present in a concentration of about 6 g/l to about 10 g/l. Other suitable reducing agents include dimethylamino borane and sodium boron hydride. The citrate stabilizing agent is preferably sodium citrate, and should be present in a concentration of about 20 g/l to about 50 g/l. Cobalt ions may be supplied by adding cobalt sulfate to the electroless plating bath in a concentration of about 5 to about 10 g/l. Ammonium tungstate may also be added to the electroless plating bath solution in a concentration of about 2 g/l to about 8 g/l. Boric acid may be added in a concentration of about 20 g/l to about 35 g/l, and a fluorocarbon surfactant such as FC 95 (available from DuPont) may be added in a concentration of about 0.1 to about 0.6 g/l. A particularly preferred composition for the electroless plating bath comprises about 7 g/l sodium hyposphosphite, about 40 g/l sodium citrate, about 6.5 g/l cobalt sulfate, about 5 g/l ammonium tungstate, about 25 g/l boric acid, and about 0.2 g/l FC 95 fluorocarbon surfactant.

In another embodiment, barrier layer 16 may be formed of an insulator material having diffusion barrier properties, such as silicon nitride or silicon carbide. A preferred silicon carbide material is BLOk™ (Barrier LOw k) dielectric film available from Applied Materials, Inc. A silicon nitride or silicon carbide barrier layer 16 is preferably deposited using a CVD or PVD process, which would result in a blanket deposition of the insulator film rather than a selective deposition on the copper stud 15.

In yet another embodiment, barrier layer 16 may be a dual layer consisting of an electrically conductive alloy selectively deposited by electroless plating on copper stud 15, as described above, and a blanket deposited insulator film.

After barrier layer 16 has been deposited, interlevel dielectric (ILD) layer 17 is applied on top of and surrounding via 15 and barrier layer 16. Dielectric layer 17 is preferably a low-k dielectric material with a dielectric constant less than 3.0. Such low-k dielectric materials may be applied by plasma-enhanced chemical vapor deposition (PE CVD), physical vapor deposition (PVD) or spin-coating methods. In one embodiment, the dielectric material is preferably an organic polymer, the most preferred of which are polyarylenes and polyarylene-ethers such as SiLK™ available from Dow Chemical. Other suitable organic dielectric materials include FLARE™ available from Allied Signal. Such polymeric films are typically applied by spin-coating methods. The dielectric material also may be a porous version of these organic polymers. Spin-coated materials such as the organic polymers mentioned above generally must be cured at high temperature, according to the cure process recommended by the dielectric material vendor. For example, SiLK dielectric films are typically cured at a temperature of 400-450° C. At 400° C., the typical cure time is 30 minutes, and at 450° C., the typical cure time is 6 minutes. In another preferred embodiment, the dielectric material is preferably a carbon-doped silicate glass film such as Black Diamond™ available from Applied Materials, CORAL™ available from Novellus, and Aurora™ available from ASM. Carbon-doped silicate glass films are typically deposited by a PE CVD process.

Next, as shown in FIG. 7, excess dielectric layer 17 and the top portion of barrier layer 16 are removed, in order to expose the top surface of copper via 15. This removal step may be performed using any suitable removal technique. If the dielectric material is a spin-coated organic polymer material, the preferred removal method is reactive ion etching (RIE). If the dielectric material is a PE CVD carbon-doped silicate glass material, the preferred removal method is chemical mechanical polishing (CMP).

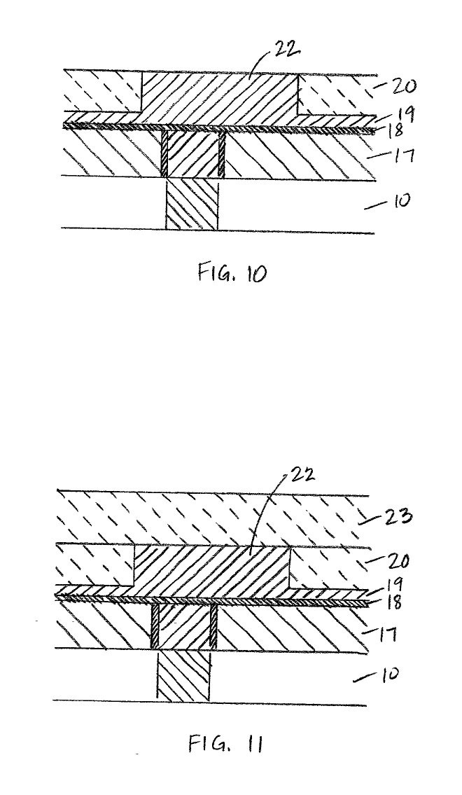

In FIGS. 8-10, the formation of the next level of interconnect wiring is shown. First, liner 18 is deposited. Liner 18 is preferably formed of a conductive material having diffusion barrier properties, such as TaN, TiN, WN, TiSiN, TaSiN, Ta, Ti and W. Next, seed layer 19 is deposited. Seed layer 19 may be formed of the same materials, and may be formed using the same processes, as seed layer 12. For copper BEOL interconnect wiring, the preferred seed layer material is copper and the preferred deposition method is PVD. Alternatively, liner 18 may serve as the seed layer for the next level of interconnect wiring. If liner 18 is formed of a material which is conducive to direct plating, such as W or CoWP, then an additional seed layer 19 is not required. For example, if the material for the interconnect wiring is copper, and liner 18 is formed of a material to which copper may be directly plated, then an additional copper seed layer is not required.

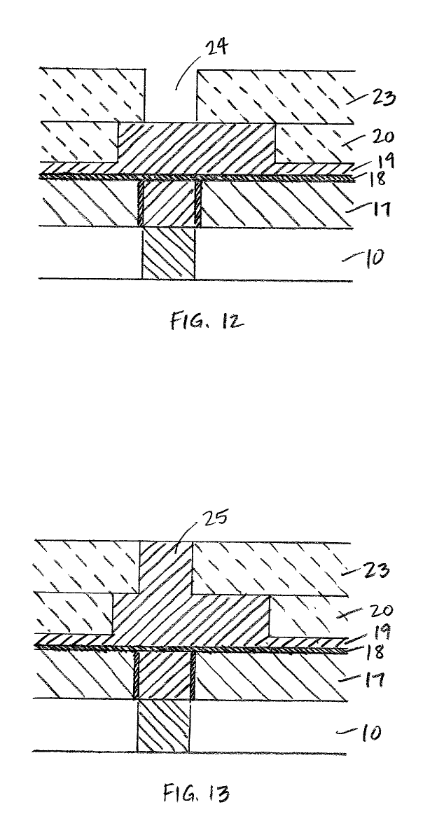

Next, photoresist layer 20 is deposited on liner 18 or seed layer 19. Again, photoresist layer 20 may be formed of the same resist materials, and may be deposited using the same processes, as photoresist layer 13. In FIG. 9, at least one opening 21 is formed in photoresist layer 20, using conventional photolithography techniques. In FIG. 10, interconnect line 22 is formed using the same selective plating methods as interconnect via 15. For copper BEOL interconnect wiring, line 22 is preferably formed by copper electrolytic plating.

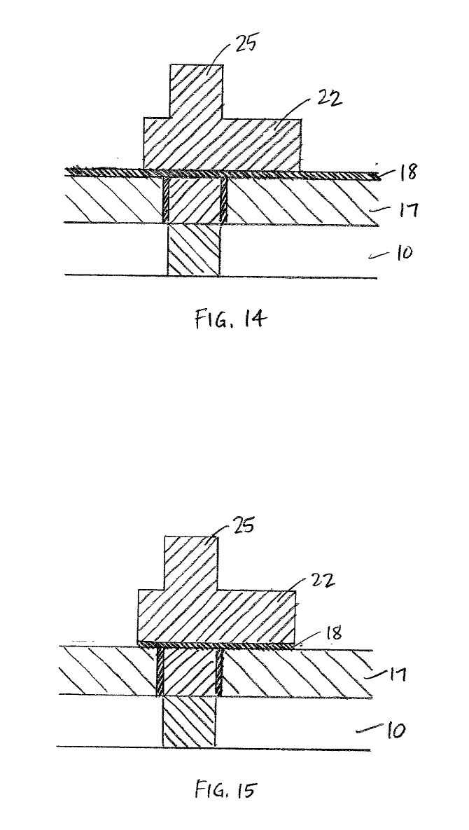

In FIGS. 11-13, the formation of the next level of interconnect wiring is shown. Photoresist layer 20 remains while photoresist layer 23 is applied. Photoresist layer 23 is preferably formed of the same material as photoresist layer 20. In FIG. 12, at least one opening 24 is formed in photoresist layer 23, using conventional photolithography techniques. In FIG. 13, interconnect via 25 is formed, preferably using the same selective plating method as line 22.

Next, photoresist layers 20 and 23 are removed, as shown in FIG. 14. Photoresist layers 20 and 23 may be removed using the same methods as for removal of photoresist layer 13.

Following removal of photoresist layers 20 and 23, seed layer 19 is removed, as shown in FIG. 14. Seed layer 19 may be removed using the same methods as for removal of seed layer 12.

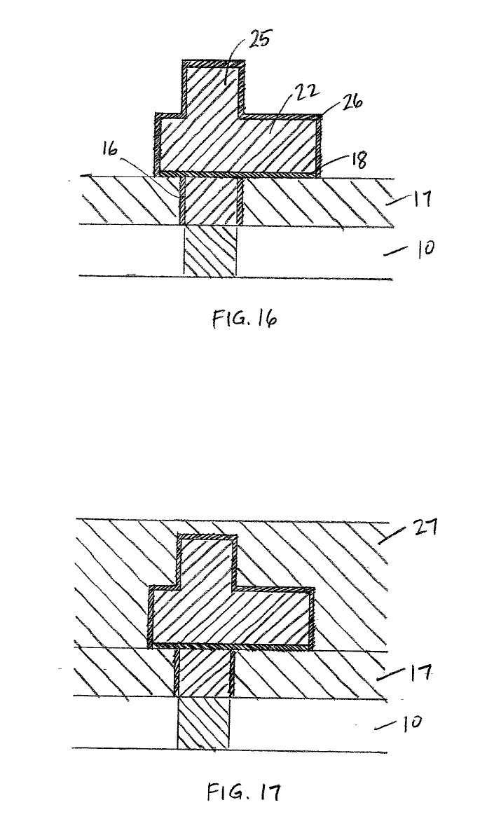

In FIG. 15, removal of exposed portions of liner 18 is shown. Liner 18 may be removed by any suitable means, such as by argon sputtering.

A conformal barrier layer 26 is then formed on via 25 and line 22, as shown in FIG. 16. Barrier layer 26 may be formed of the same materials as for barrier layer 16. Thus, barrier layer 26 may be formed of an electrically conductive material which is selectively deposited by the same electroless plating process discussed previously for barrier layer 16. Alternatively, barrier layer 26 may be formed of an insulator material such as silicon nitride or silicon carbide which is blanket deposited by a CVD or PVD process. Barrier layer 26 may also be a dual layer consisting of electrically conductive alloy selectively deposited by electroless plating, and a blanket deposited insulator material.

After deposition of barrier layer 26, dielectric layer 27 is applied on top of and surrounding via 25, line 22 and barrier layer 26. Dielectric layer 27 is preferably a low-k dielectric material with a dielectric constant less than 3.0, and may be formed of the same materials and using the same methods as dielectric layer 17.

Finally, a CMP or RIE step is performed to remove excess dielectric layer 27 and the top portion of barrier layer 26, in order to expose the top surface of copper via 25.

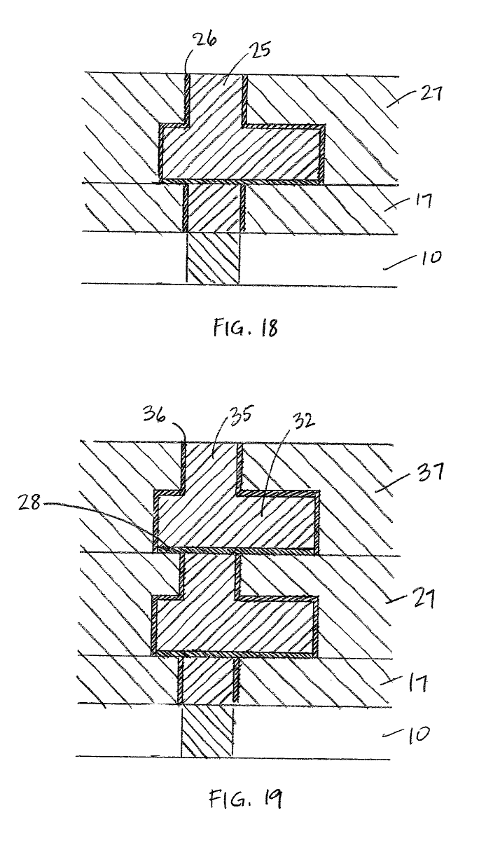

The steps shown in FIGS. 11-18 may be repeated to form subsequent layers of interconnect wiring, as shown in FIG. 19.

The method of this invention provides several advantages over prior art methods of forming interconnect structures. First, the method of this invention does not require patterning of the ILD material using conventional photolithographic processes. Second, the selective electroless liner deposition process or non-selective blanket insulator capping process of this invention produces uniform and conformal liner coverage around copper wires.

Moreover, having a metal diffusion barrier on all four sides of the interconnect in accordance with this invention provides protection against copper diffusion and electromigration which is superior to most convention diffusion barrier layers. For example, dual damascene interconnect structures are typically capped with a dielectric material such as silicon nitride to provide a diffusion barrier at the top surface of the copper interconnects. However, silicon nitride is relatively ineffective for prevention of copper electromigration, and also suffers from poor adhesion to the copper surface. In addition, silicon nitride has a relatively high dielectric constant of about 6 or 7, thereby increasing the effective dielectric constant in the circuit. Other dielectric materials have been investigated for use in this diffusion barrier cap layer, such as BLOk™ (an amorphous film composed of silicon carbon and hydrogen, available from Applied Materials, Inc.), but none has been shown to be as effective as an electroless layer such as CoWP plated on the Cu lines. This electroless CoWP layer increases by a factor of 2 or more the electromigration resistance.

Another advantage of this invention is that no excessive metal CMP step is required to remove the metal overburden as is common in conventional damascene processes. In the TMP process of this invention, plating occurs from the bottom of the vias, and the level of plated copper gradually rises to the surface. As a result, the overplating of the surface can be controlled and the overburden is minimized. The subsequent CMP step illustrated in FIG. 7, wherein excess dielectric layer 17 and the top portion of barrier layer 16 is removed in order to expose the top surface of copper via 15, is simpler and less costly than the CMP step typically required in a dual damascene process.

Yet another advantage of the method of this invention is the lower cost resulting from replacement of vacuum liner deposition processes with the selective electroless liner plating process to form the diffusion barrier layer. Electroless liner deposition equipment is less costly than typical vacuum deposition equipment, and the process steps involved with electroless liner deposition are also simpler and less costly.

While the present invention has been particularly described in conjunction with a specific preferred embodiment and other alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the present invention.

We claim:

1. A method for forming a metal interconnect in an integrated circuit device, the method comprising the steps of:
(a) depositing a metal seed layer onto a partially fabricated integrated circuit device;
(b) depositing a photoresist layer onto the metal seed layer;
(c) forming an opening in the photoresist layer by a photolithography process, thereby exposing a portion of the metal seed layer;
(d) depositing metal in the opening by a plating process;
(e) removing the photoresist layer and metal seed layer, thereby exposing the partially fabricated integrated circuit device;
(f) depositing a conformal barrier layer onto the metal; and
(g) depositing a dielectric material onto the partially fabricated integrated circuit device.

2. The method of claim 1, wherein the metal seed layer is formed of a material to which the metal is directly plated.

3. The method of claim 1, wherein the metal seed layer is copper.

4. The method of claim 1, wherein the metal is deposited by an electrolytic plating process.

5. The method of claim 1, wherein the metal is deposited by an electroless plating process.

6. The method of claim 1, wherein the metal is copper, and the copper is deposited by an electrolytic plating process comprising the steps of:
immersing the partially fabricated integrated circuit device into a plating bath comprising a dissolved cupric salt; and
applying electric current to the metal seed layer.

7. The method of claim 1, wherein the barrier layer is selectively deposited onto the metal by an electroless plating process.

8. The method of claim 7, wherein the electroless plating process comprises the steps of:
depositing catalytic particles onto the surface of the metal; and
immersing the partially fabricated integrated circuit device into a plating bath.

9. The method of claim 8, wherein the metal is copper; the catalytic particles are selected from a group consisting of palladium, cobalt and nickel; and the plating bath comprises a hypophosphite reducing agent.

10. The method of claim 1, wherein the barrier layer is selected from a group consisting of CoWP, CoP, NiP, NiWP, CoB, NiB and CoWB.

11. The method of claim 1, wherein the barrier layer is formed of an insulator material.

12. The method of claim 1, wherein the barrier layer is deposited by a chemical vapor deposition process or physical vapor deposition process.

13. The method of claim 1, wherein the barrier layer comprises a first layer of material selected from the group consisting of CoWP, CoP, NiP, NiWP, CoB, NiB and CoWB, and a second layer of insulator material.

14. The method of claim 1, wherein the dielectric material is deposited by a chemical vapor deposition process, a physical vapor deposition process, or a spin-coating process.

15. The method of claim 1, wherein the dielectric material has a dielectric constant of less than about 3.0.

16. The method of claim 1, wherein the dielectric material comprises an organic polymer material, and is deposited by spin-coating the dielectric material onto the partially fabricated integrated circuit device.

17. The method of claim 1, wherein the dielectric material comprises a carbon-doped silicate glass, and is deposited by a plasma-enhanced chemical vapor deposition process.

18. The method of claim 1, further comprising the step of:
(h) removing excess dielectric material and the top portion of the barrier layer, thereby exposing the top surface of the metal.

19. The method of claim 1, further comprising repeating steps (c) through (e), prior to performing step (f).

20. The method of claim 1, further comprising, prior to step (a), the step of:
depositing a conductive barrier liner onto the partially fabricated integrated circuit device.
